(19) United States
(12) Patent Application Publication
(10) Pub. No.: US 2010/0241920 A1
(43) Pub. Date: Sep. 23, 2010

(54) IMAGE DECODING APPARATUS, IMAGE DECODING METHOD, AND COMPUTER-READABLE RECORDING MEDIUM

(75) Inventor: Nobuhiro Nonogaki, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/613,995

(22) Filed: Nov. 6, 2009

(30) Foreign Application Priority Data
Mar. 23, 2009 (JP) 2009-070779

(51) Int. Cl. H03M 13/05; G06F 11/10

(52) U.S. Cl. 714/752; 714/E11.032

(57) ABSTRACT

An image decoding apparatus is an image decoding apparatus that parses an input bit stream to extract decode parameters and generates a decoded image based on the decode parameters. The image decoding apparatus includes: an error position/recovery position detecting unit that detects an error position and a recovery position in the decode parameters and discards the decode parameters in the error position to the recovery position; and an interpolated-decode-parameter inserting unit that interpolates the decode parameters discarded by the error position/recovery position detecting unit.

### CROSS-REFERENCE TO RELATED APPLICATIONS

This application is based upon and claims the benefit of priority from the prior Japanese Patent Applications No. 2009-070779, filed on Mar. 23, 2009, the entire contents of which are incorporated herein by reference.

### BACKGROUND OF THE INVENTION

1. Field of the Invention

The present invention relates to an image decoding apparatus, an image decoding method, and a computer-readable recording medium.

2. Description of the Related Art

Encoding and decoding technologies for moving images are demanded to be, for example, high in compression efficiency, high in quality during decoding, and high in transmission efficiency because an amount of information of the moving images is large. As an encoding and decoding technology for moving images that meets these demands, there is a technology called ITU-T recommendation H.264/AVC (Advanced video coding).

For example, H.264/AVC is applied to a terrestrial digital broadcast for mobile stations, a mobile broadcast, and the like. When a receiving terminal is a mobile terminal represented by a portable terminal or a vehicle-mounted terminal, the receiving terminal moves. Therefore, it cannot be expected that the receiving terminal always receives stream data in a stable radio wave environment. In particular, in an environment in which the receiving terminal is hidden behind a building or the like, errors are highly frequently mixed in the stream data. Therefore, an error resistant function is essential in a moving image decoding apparatus. Various examinations are performed concerning the moving image decoding apparatus.

As a technology for reducing a degree of a failure of a moving image and improving a subjective image quality under an environment in which an error of data and missing of data tend to occur on a communication path, for example, JP-A 2002-77922(KOKAI) is proposed. In a technology disclosed in TP-A 2002-77922(KOKAI), a transmission side encodes an image, generates an I picture and a P picture, and transmits an identification flag for identifying the I picture and the P picture and a frame sequence including the I picture and the P picture. A reception side calculates a correlation value of a preceding frame and a present frame in the received frame sequence, determines, using at least one of information concerning the identification flag and the correlation value, whether an error concealing frame used in concealing an error should be the preceding frame or the present frame, and adaptively performs error concealment to decode the image using the determined error concealing frame.

However, because error concealing control is performed in signal processing having a large processing amount, when processing substantially different from processing at normal time is performed, highly efficient parallelism during normal time is hindered. Therefore, decoding processing cannot be highly efficiently performed.

### SUMMARY OF THE INVENTION

An image decoding apparatus according to an embodiment of the present invention is for parsing an input bit stream to extract decode parameters and generates a decoded image based on the decode parameters. The image decoding apparatus includes an error position/recovery position detecting unit that detects an error position and a recovery position in the decode parameters and discards the decode parameters in the error position to the recovery position, and an interpolated-decode-parameter inserting unit that interpolates the decode parameters discarded by the error position/recovery position detecting unit.

An image decoding method according to an embodiment of the present invention is for parsing an input bit stream to extract decode parameters and generating a decoded image based on the decode parameters. The image decoding method includes detecting an error position and a recovery position in the decode parameters and discarding the decode parameters in the error position to the recovery position, and interpolating the discarded decode parameters.

A computer-readable recording medium according to an embodiment of the present invention is having recorded thereon a computer program for causing a computer to parse an input bit stream to extract decode parameters and generate a decoded image based on the decode parameters. The computer program causes the computer to detect an error position and a recovery position in the decode parameters and discard the decode parameters in the error position to the recovery position, and interpolate the discarded decode parameters.

### BRIEF DESCRIPTION OF THE DRAWINGS

FIG. 1 is a diagram of a schematic configuration example of an image decoding apparatus according to an embodiment of the present invention;

FIG. 2 is a schematic diagram for explaining error concealment processing performed by an error position/recovery position detecting unit and an interpolated-decode-parameter inserting unit;

FIG. 3 is a state transition diagram of a state of the error position/recovery position detecting unit;

FIG. 4 is a flowchart for explaining a processing flow of decode parameter error detection performed by the error position/recovery position detecting unit;

FIG. 5 is a diagram of an example of a unit of syntax elements in performing error detection;

FIG. 6 is a flowchart for explaining a first example (in the case of simple determination) of an interpolation type determination flow of the interpolated-decode-parameter inserting unit; and

FIG. 7 is a flowchart for explaining a second example of the interpolation type determination flow of the interpolated-decode-parameter inserting unit.

### DETAILED DESCRIPTION OF THE PREFERRED EMBODIMENTS

Exemplary embodiments of the present invention are explained in detail below with reference to the accompanying drawings. The present invention is not limited by the embodiments. Components in the embodiments explained below include components that can be easily conceived by those skilled in the art or components substantially the same as the components. In the embodiments, an H.264/AVC decoder is explained as an example of an image decoding apparatus.

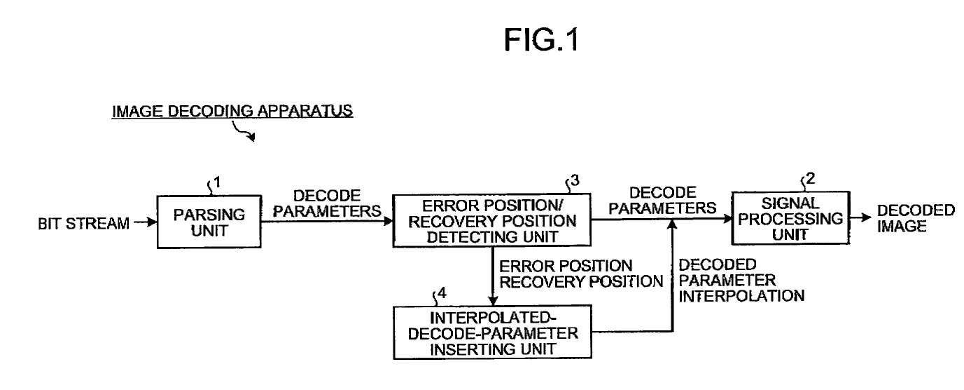

FIG. 1 is a diagram of a schematic configuration example of an image decoding apparatus according to an embodiment of the present invention. The image decoding apparatus according to this embodiment includes, as shown in FIG. 1, a parsing unit 1 and a signal processing unit 2. The image decoding apparatus further includes an error position/recovery position detecting unit 3 and an interpolated-decode-parameter inserting unit 4 between the parsing unit 1 and the signal processing unit 2.

The parsing unit 1 applies H.264/AVC Syntax parsing processing to a bit stream of an input image signal and extracts (decodes) and outputs decode parameters.

The signal processing unit 2 performs predetermined signal processing according to the decode parameters extracted by the parsing unit 1 and generates a decoded image. In H.264/AVC, the predetermined signal processing is, for example, motion vector prediction processing, motion compensation processing, intra prediction processing, inverse DCT processing, weighted prediction processing, and deblocking filter processing.

Because a publicly-known configuration of the H.264/AVC decoder can be used for the parsing unit 1 and the signal processing unit 2, detailed explanation thereof is omitted.

The error position/recovery position detecting unit 3 and the interpolated-decode-parameter inserting unit 4 are arranged between the parsing unit 1 and the signal processing unit 2 and perform error concealment processing. In this embodiment, when the error concealment processing is performed, the error concealment processing is determined only with decode parameters. Therefore, it is unnecessary to perform, in signal processing, processing involving backtracking and processing other than processing specified in H.264/AVC. The parsing unit 1 and the signal processing unit 2 can maintain high parallelism.

The error position/recovery position detecting unit 3 detects an error start position and a recovery position in the decode parameters, and discards the decode parameters from the error start position to the recovery position. The interpolated-decode-parameter inserting unit 4 interpolates the decode parameters discarded by the error position/recovery position detecting unit 3.

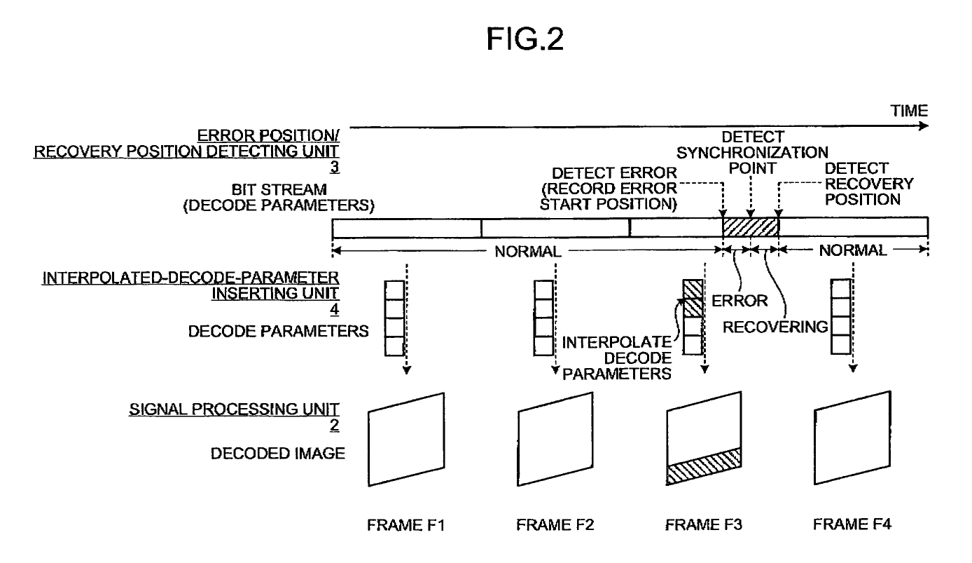

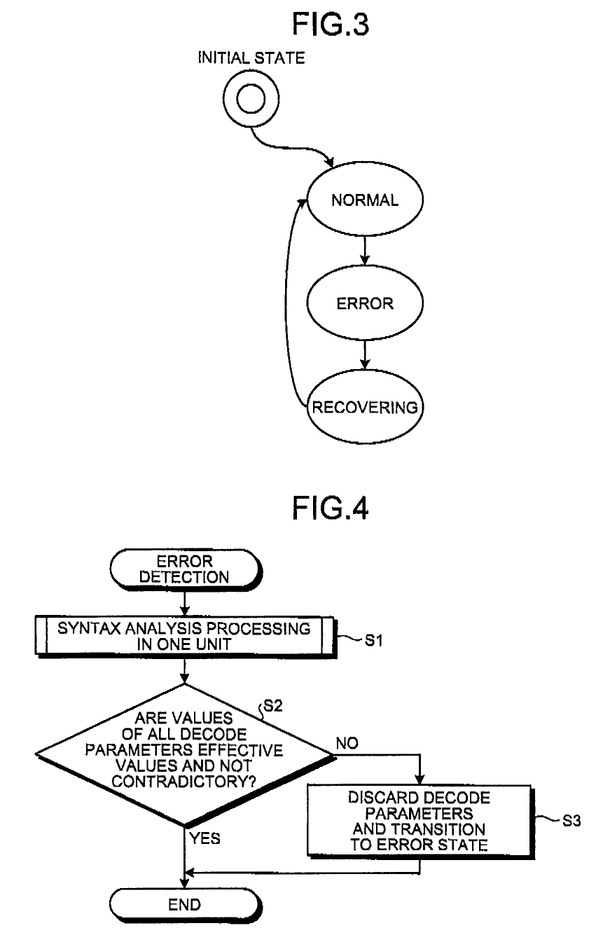

FIG. 2 is a schematic diagram for explaining the error concealment processing performed by the error position/recovery position detecting unit 3 and the interpolated-decode-parameter inserting unit 4. FIG. 3 is a state transition diagram of a state of the error position/recovery position detecting unit 3. As shown in FIG. 3, the error position/recovery position detecting unit 3 has three states, i.e., a “normal” state, an “error” state, and a “recovering” state. The error position/recovery position detecting unit 3 performs processing such as inspection, discarding, and interpolation of the decode parameters according to the respective states.

In FIGS. 2 and 3, an initial state of the error position/recovery position detecting unit 3 is the “normal”. The error position/recovery position detecting unit 3 starts operation assuming that correct decode parameters sent from the parsing unit 1 are input. The error position/recovery position detecting unit 3 executes, in the “normal” state, error detection processing for the decode parameters every time processing of one unit of various syntax elements in the parsing unit 1 is completed. When an error is detected, the error position/recovery position detecting unit 3 records an error position (an error start position), notifies the parsing unit 1 of the error to seek a synchronized position of a predetermined start code, a resync marker, or the like, and changes to the “error” state.

In the “error” state, the error position/recovery position detecting unit 3 discards, irrespective of what kinds of decode parameters are input from the parsing unit 1, all the decode parameters until a synchronization point of the start code, the resync marker, or the like is detected. When a synchronization position is detected, the error position/recovery position detecting unit 3 changes to the “recovering” state.

In the “recovering” state, the error position/recovery position detecting unit 3 analyzes decode parameters sent from the parsing unit 1, specifies a recovery position in signal processing, and, when the recovery position is specified, changes to the “normal” state. Specifically, the error position/recovery position detecting unit 3 takes notice of a parameter given as a continuous number frame num added to a slice header and, when it is confirmed that the parameter is a number continuous once or more times, treats this slice as a recovery position. In the “recovering” state, the error position/recovery position detecting unit 3 discards the decode parameters sent from the parsing unit 1. In this way, the decode parameters in the error position to the recovery position are discarded.

After the recovery position is decided, the interpolated-decode-parameter inserting unit 4 collects, with this range set as an interpolation range, the decode parameters discarded between the error position and the recovery position and inserts an interpolated decode parameter. In an example shown in FIG. 3, there is an error in decode parameters of a frame F3 and the decode parameters are interpolated.

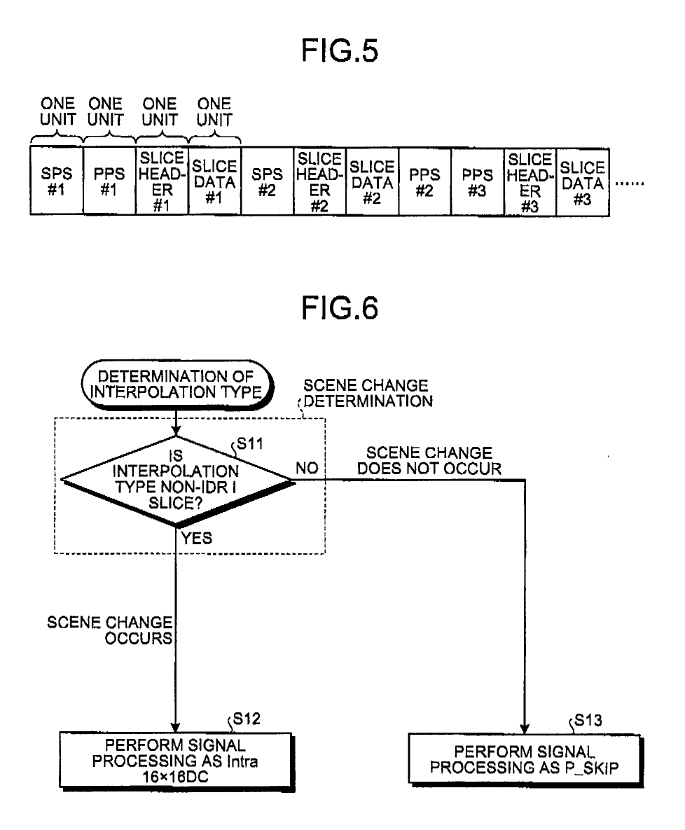

FIG. 4 is a flowchart for explaining a processing flow of decode parameter error detection by the error position/recovery position detecting unit 3. FIG. 5 is a diagram of an example of a unit of syntax elements in performing error detection.

In FIG. 4, in the “normal” state, the error position/recovery position detecting unit 3 determines, every time the analysis of one unit (e.g., a picture parameter set (PPS), a sequence parameter set (SPS), a slice header, or slice data) of various syntax elements is completed in the parsing unit 1 (step S1), whether values of all decode parameters of the unit are within an effective range and there is no contradiction among data (data are consistent), i.e., the decode parameters are normal (step 52). In the example shown in FIG. 5, the error position/recovery position detecting unit 3 performs error detection with the picture parameter set (PPS), the sequence parameter set (SPS), the slice header, and the slice data set as units.

When the values of all the decode parameters are within the effective range and there is no contradiction among the data, i.e., the decode parameters are normal (“Yes” at step S2), the error position/recovery position detecting unit 3 directly transmits the decode parameters to the signal processing unit 2.

When the values of the decode parameters are not within the effective range and the data contradict one another, i.e., the decode parameters are unusual (“No” at step S2), the error position/recovery position detecting unit 3 discards the decode parameters and changes to the error state (step S3).

FIG. 6 is a flowchart for explaining a first example (in the case of simple determination) of an interpolation type determination flow of the interpolated-decode-parameter inserting unit 4. The interpolated-decode-parameter inserting unit 4 determines, according to a slice type of an error position, a macro block type of decode parameters to be interpolated.

In FIG. 6, the interpolated-decode-parameter inserting unit 4 determines whether a slice type of an error position is a non-IDR slice and is an I slice (step S11). An IDR slice means a refresh frame inserted to enable reproduction from the middle during broadcasting or the like.

When the slice type is the non-IDR slice and is the I slice (“Yes” at step S1), the interpolated-decode-parameter inserting unit 4 regards that a scene change occurs and interpolates decode parameters of an Intra 16×16 DC macro block type (intra prediction) (step S12).

When the slice type is not the non-IDR slice and is not the I slice, i.e., the slice type is the IDR slice, a P slice, or a B slice (“No” at step S11), the interpolated-decode-parameter inserting unit 4 interpolates decode parameters of a P_SKIP macro block type (motion compensation) (step S13).

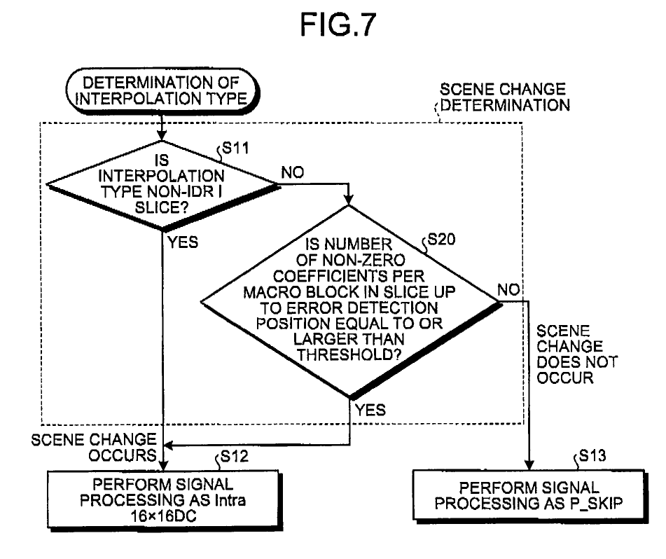

FIG. 7 is a flowchart for explaining a second example of the interpolation type determination flow of the interpolated-decode-parameter inserting unit 3. In the second example, detection of a scene change is highly accurately performed. Steps for performing kinds of processing same as those shown in FIG. 6 are denoted by the same step numbers. Only differences are explained below.

In FIG. 7, when the slice type of the error position is not the non-IDR slice and is not the I slice, i.e., the slice type is the IDR slice, the P slice, or the B slice (“No” at step S11), the interpolated-decode-parameter inserting unit 4 takes notice of a total number of non-zero coefficients in a coefficient matrix for inverse DCT processing present in the decode parameters and determines whether the number of non-zero coefficients per one macro block in the slice up to the error position is equal to or larger than an experimentally-determined threshold (step S20). When the number of non-zero coefficients per one macro block in the slice up to the error position is equal to or larger than the experimentally-determined threshold (“Yes” at step S12), the interpolated-decode-parameter inserting unit 4 regards that a scene change occurs and interpolates decode parameters of the Intra 16×16 DC macro block type (step S12). When the number of non-zero coefficients per one macro block in the slice up to the error position is not equal to or larger than the experimentally-determined threshold (“No” at step S12), the interpolated-decode-parameter inserting unit 4 interpolates decode parameters of the P_SKIP macro block type (step S13).

The image decoding apparatus according to this embodiment can be realized by hardware or software. When the image decoding apparatus is realized by software, this can also be attained by supplying a recording medium having recorded thereon a program code of software for realizing the functions of the image decoding apparatus to a system or an apparatus and a computer (or a central processing unit (CPU), a micro processor unit (MPU), or a digital signal processor (DSP)) of the system or the apparatus executing the program code stored in the recording medium. In this case, the program code itself read out from the recording medium realizes the functions of the image decoding apparatus. The recording medium having the program code or a computer program thereof is included in the present invention. As the recording medium for supplying the program code, optical recording media, magnetic recording media, magneto-optical recording media, and semiconductor recording media such as a FD, a hard disk, an optical disk, a magneto-optical disk, a compact disk-read only memory (CD-ROM), a compact disk-recordable (CD-R), a digital versatile disk-read only memory (ROM)/random access memory (RAM), a magnetic tape, a nonvolatile memory, and a read only memory (ROM) can be used.

The functions of the image decoding apparatus are not only realized by the computer executing the read-out program code. It goes without saying that an operating system (OS) or the like running on the computer performs, based on an instruction of the program code, a part or all of actual processing and the functions of the image decoding apparatus are realized by the processing.

As explained above, according to this embodiment, the image decoding apparatus includes the error position/recovery position detecting unit 3 that detects an error position and a recovery position in decode parameters and discards the decode parameters in the error position to the recovery position and the interpolated-decode-parameter inserting unit 4 that interpolates the decode parameters discarded by the error position/recovery position detecting unit 3. Therefore, it is possible to prevent deterioration in a subjective image quality with respect to an error included in a code while highly accurately performing decode processing. Further, the error position/the recovery position and the interpolation are determined only with the decode parameters without depending on signal processing. Therefore, it is unnecessary to perform, in the signal processing, processing involving backtracking and processing other than processing specified in H.264/AVC. It is possible to maintain high parallelism with the processing of the parsing unit 1 and the signal processing unit 2.

According to this embodiment, the error position/recovery position detecting unit 3 detects a recovery position by confirming that frame_num included in the slice header continuously increases. Therefore, it is possible to easily and accurately detect the recovery position.

According to this embodiment, the interpolated-decode-parameter inserting unit 4 detects a scene change based on decode parameters. When a scene change is detected, the interpolated-decode-parameter inserting unit 4 interpolates the decode parameters of intra prediction. When a scene change is not detected, the interpolated-decode-parameter inserting unit 4 interpolates the decode parameters of motion compensation. Therefore, it is possible to prevent deterioration in a subjective image quality even if a scene change occurs.

According to this embodiment, when the slice type is the non-IDR slice and is the I slice or when the number of non-zero coefficients of the macro block in the normally-decoded slice is equal to or larger than the threshold, the interpolated-decode-parameter inserting unit 4 determines that a scene change occurs. Therefore, it is possible to highly accurately detect a scene change.

In the embodiments, the H.264/AVC standard is applied to the image decoding apparatus as an example. However, the present invention is not limited to this. For example, the present invention can also be applied to other standards such as MPEG2, MPEG4, VC1, H.263 standards.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An image decoding apparatus that parses an input bit stream to extract decode parameters and generates a decoded image based on the decode parameters, the image decoding apparatus comprising:
an error position/recovery position detecting unit that detects an error position and a recovery position in the decode parameters and discards the decode parameters in the error position to the recovery position; and
an interpolated-decode-parameter inserting unit that interpolates the decode parameters discarded by the error position/recovery position detecting unit.

2. The image decoding apparatus according to claim 1, wherein the error position/recovery position detecting unit detects the recovery position by confirming that frame_num included in a slice header continuously increases.

3. The image decoding apparatus according to claim 1, wherein the interpolated-decode-parameter inserting unit detects a scene change based on the decode parameters, interpolates the decode parameters of intra prediction when a scene change is detected, and interpolates the decode parameters of motion compensation when a scene change is not detected.

4. The image decoding apparatus according to claim 3, wherein the interpolated-decode-parameter inserting unit determines that a scene change occurs when a slice type of the error position is a non-IDR slice and is an I slice or when a number of non-zero coefficients of a macro block in a normally-decoded slice is equal to or larger than a threshold.

5. The image decoding apparatus according to claim 1, wherein the image decoding apparatus conforms to H.264/AVC.

6. An image decoding method for parsing an input bit stream to extract decode parameters and generating a decoded image based on the decode parameters, the image decoding method comprising:
detecting an error position and a recovery position in the decode parameters and discarding the decode parameters in the error position to the recovery position; and
interpolating the discarded decode parameters.

7. The image decoding method according to claim 6, wherein the detecting the recovery position includes detecting the recovery position by confirming that frame_num included in a slice header continuously increases.

8. The image decoding method according to claim 6, wherein the interpolating the decode parameters includes detecting a scene change based on the decode parameters, interpolating the decode parameters of intra prediction when a scene change is detected, and interpolating the decode parameters of motion compensation when a scene change is not detected.

9. The image decoding method according to claim 8, wherein the interpolating the decode parameters includes determining that a scene change occurs when a slice type of the error position is a non-In slice and is an I slice or when a number of non-zero coefficients of a macro block in a normally-decoded slice is equal to or larger than a threshold.

10. A computer-readable recording medium having recorded thereon a computer program for causing a computer to parse an input bit stream to extract decode parameters and generate a decoded image based on the decode parameters, the computer program causing the computer to:
detect an error position and a recovery position in the decode parameters and discard the decode parameters in the error position to the recovery position; and
interpolate the discarded decode parameters.

11. The computer-readable recording medium according to claim 10, wherein the computer program causes the computer to detect, in the detection of the recovery position, the recovery position by confirming that frame_num included in a slice header continuously increases.

12. The computer-readable recording medium according to claim 10, wherein the computer program causes, in the interpolation of the decode parameters, the computer to detect a scene change based on the decode parameters, interpolate the decode parameters of intra prediction when a scene change is detected, and interpolate the decode parameters of motion compensation when a scene change is not detected.

13. The computer-readable recording medium according to claim 12, wherein the computer program causes, in the interpolation of the decode parameters, the computer to determine that a scene change occurs when a slice type of the error position is a non-IDR slice and is an I slice or when a number of non-zero coefficients of a macro block in a normally-decoded slice is equal to or larger than a threshold.
